(19) United States
(12) Patent Application Publication
(10) Pub. No.: US 2003/0173651 A1
(43) Pub. Date: Sep. 18, 2003

(54) Method of making a semiconductor device using a damascene interconnect with a laminated dielectric

(76) Inventors: Lawrence D. Wong, Beaverton, OR (US); Jihperng Leu, Portland, OR (US); Grant Kloster, Hillsboro, OR (US); Andrew Ott, Hillsboro, OR (US); Patrick Morrow, Portland, OR (US)

Correspondence Address: KENYON & KENYON, 1500 K STREET, N.W., SUITE 700, WASHINGTON, DC, 20005, US

(21) Appl. No.: 10/097,328

(22) Filed: Mar. 15, 2002

(51) Int. Cl. H01L 21/4763

(52) U.S. Cl. 257/633

(57) ABSTRACT

A method of fabricating a semiconductor device includes laminating a dielectric sheet on a substrate and forming a via opening in the dielectric sheet. The method further includes depositing a conductive material into the first via opening.

### FIELD OF THE INVENTION

The present invention is directed to integrated circuit processing. More particularly, the present invention is directed to the fabrication of interconnects on an integrated circuit.

### BACKGROUND INFORMATION

Modern integrated circuits use conductive interconnects to connect the individual devices on a chip or to send and/or receive signals external to the chip. Popular interconnect materials include copper, aluminum, copper alloys, and aluminum alloys. In order to accommodate desired interconnect densities, multiple layers of interconnects, referred to as “metallization layers” may be used.

A typical method of forming an interconnect, particularly a copper interconnect, is a damascene process. A common conventional damascene process usually involves the following, as illustrated by FIG. 1:

(1) Deposit an etch stop 120 on a substrate 110.

(2) Deposit a dielectric layer 130. Because dielectric layer 130 will ultimately fill the space between interconnects within a particular layer, it may be referred to as an interlayer dielectric or ILD.

(3) Form a trench 132 having via openings 134 in the dielectric layer 130 and etch stop 120 to an underlying layer, such as substrate 110. For example, via openings 134 may expose the source, drain, or gate of a transistor. A hard mask 140 may be used to form the trench, but is not necessary. Structure 11 shows a partially fabricated interconnect layer after step 3.

(4) Line the trench 132 and via opening 134 with a barrier layer of a refractory material, for example titanium nitride (TiN), tantalum (Ta) or tantalum nitride (TaN). The barrier layer serves to inhibit the diffusion of the interconnect material that will subsequently be introduced in the via and trench into the interlayer dielectric.

(5) Deposit a suitable seed material on the wall or walls of trench 132 and via opening 134. Suitable seed materials for the deposition of copper interconnect material include copper (Cu), nickel (Ni), and cobalt (Co).

(6) Deposit an interconnect material 150, such as copper, into the trench and via openings. Deposition methods include electroplating and physical deposition. Structure 12 shows a partially fabricated interconnect layer after step 6.

(7) Planarize to remove any excess interconnect material and to form interconnect 160. Structure 13 shows an interconnect layer after step 7.

Steps 1 through 7 may be repeated multiple times to fabricate multiple layers of metallization. After the final layer of metallization is fabricated, a dielectric material may be deposited to isolate the structure.

Although many different materials have been used as interconnect materials, copper has become a popular choice for various reasons. For example, copper has a low resistively and a high melting point compared to aluminum or aluminum alloys. Low resistively enables the use of thinner interconnects without sacrificing conductivity, and high melting point decreases susceptibility to migration during operation, which can lead to undesirable voids in the interconnect.

As chip processing technology advances and the packing density of devices increases, it is desirable to similarly increase the density of interconnects. This may be achieved by reducing the interconnect metal pitch, and by increasing the number of metallization levels. However, reduced interconnect pitch and/or increased metallization levels may lead to problems such as increased capacitance between interconnects on the same plane, and between interconnects between layers. Increased parasitic capacitance can cause undesirable effects such as RC delay, power dissipation, and capacitively coupled signals, also known as cross-talk.

One way to reduce the unwanted capacitance between the interconnects is to increase the distance between them. However, increased spacing between interconnects has adverse consequences such as increased area requirements, and corresponding increases in manufacturing costs.

Based on the foregoing, there is a need for a simplified fabrication method to form damascene interconnects and a method to reduce capacitance between interconnects.

### BRIEF DESCRIPTION OF THE DRAWINGS

FIG. 1 illustrates a common conventional damascene process.

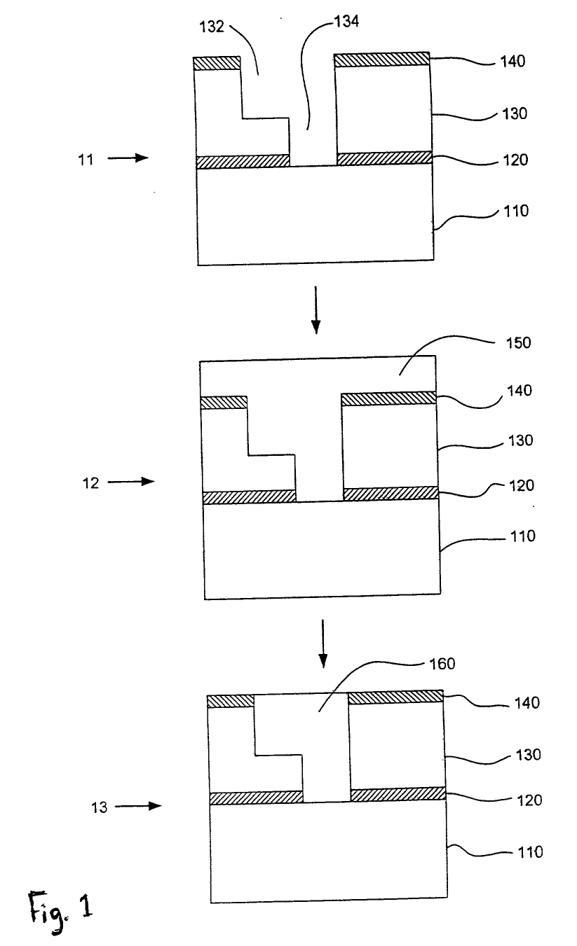

FIG. 2 illustrates a method of fabricating a semiconductor device in accordance with one embodiment of the present invention.

FIG. 3 illustrates a method of fabricating a semiconductor device in accordance with another embodiment of the present invention.

### DETAILED DESCRIPTION

One embodiment of the present invention utilizes a laminate sheet as an ILD when creating a damascene structure. The laminate sheet can avoid the need for a diffusion barrier between layers, and can be removed, leaving behind an air gap that functions as an improved dielectric. The use of a laminate sheet also simplifies the fabrication process.

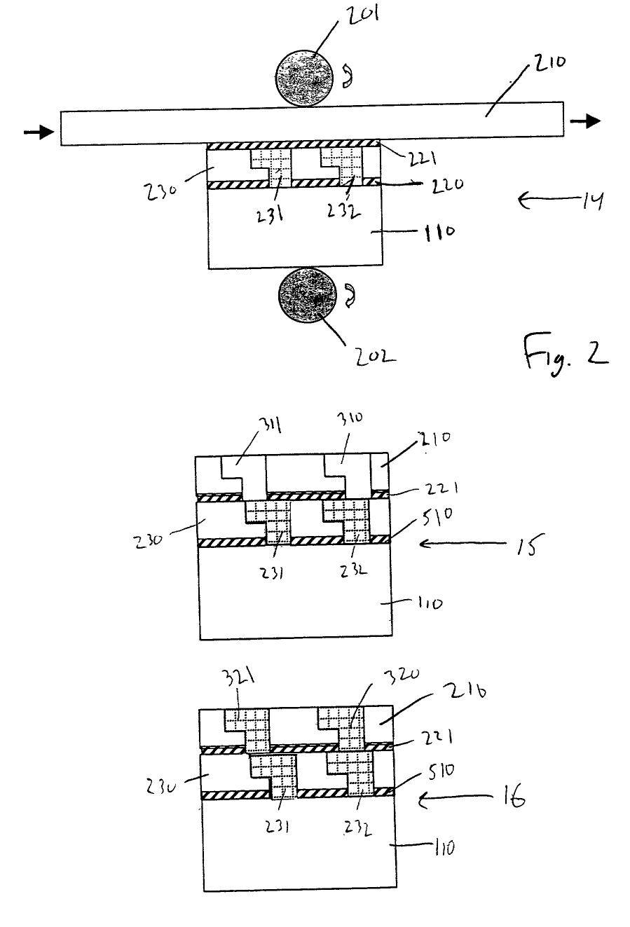

FIG. 2 illustrates a method of fabricating a semiconductor device in accordance with one embodiment of the present invention.

Structure 14 has a substrate layer 110, and a preexisting interconnect layer that includes an etch stop diffusion barrier 220, interconnects 231, 232, and dielectric 230. The preexisting layer may have been formed by prior art methods, or by the methods in accordance with the present invention.

A diffusion barrier 221 is placed over the preexisting layer. In other embodiments, a diffusion barrier is not used and the new interconnect layer placed directly on top of the preexisting layer.

A sheet of dielectric film 210 in the form of a low dielectric constant laminate sheet is laminated on diffusion barrier 221. In one embodiment, roller bars 201, 202 laminate laminate sheet 210 on diffusion barrier 221. In other embodiments, laminate sheet 210 may be laminated using a press operation. Laminate sheet 210 can be formed from a single ILD lamella, a multilayer lamella, or a composite material.

Trenches 310, 311 having via openings are formed in laminate sheet 210, as shown on structure 15. Laminate sheet 210 is also trimmed and cured.

Finally, a suitable seed material is placed on the walls of trenches 310, 311 and an interconnect material 320, 321, such as copper, is deposited, as shown on structure 16. Interconnect material 320, 321 may be polished or otherwise treated to form a conductive interconnect layer.

The use of laminate sheet 210 to form structure 16 provides advantages over prior art that applies an ILD by the use of expensive film deposition such as chemical vapor deposition (“CVD”) or spin-on techniques.

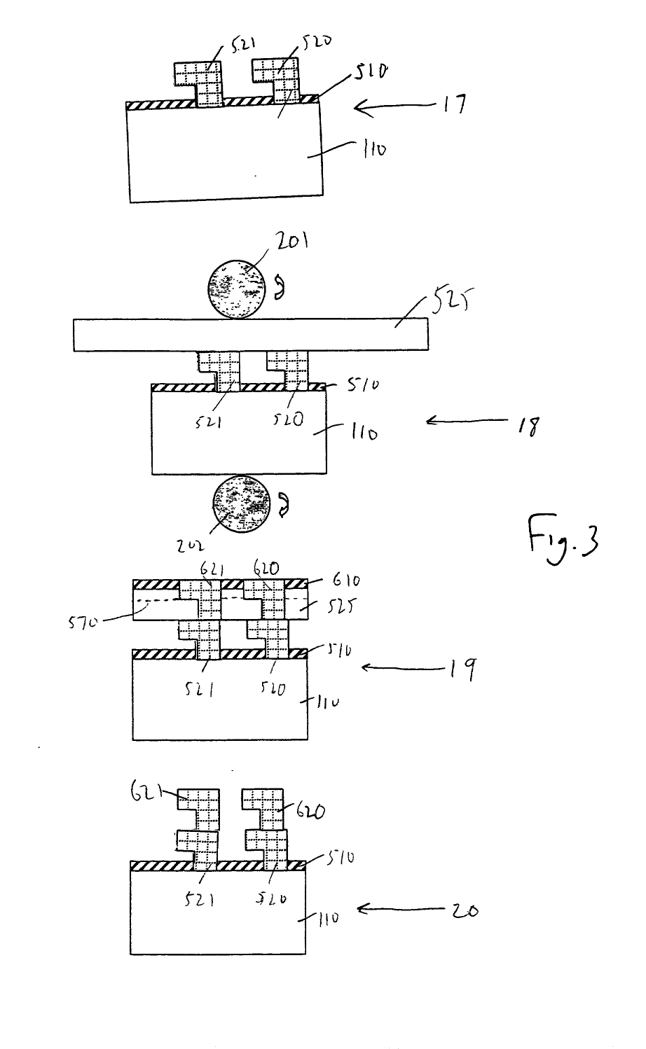

FIG. 3 illustrates a method of fabricating a semiconductor device in accordance with another embodiment of the present invention. Structure 17 has substrate 110, diffusion barrier 510, and interconnects 520, 521 that are formed similar to interconnects 320, 321 except that the laminate sheet is removed after interconnects 520, 521 are formed.

A laminate sheet 525 is laminated on interconnects 520, 521 by rollers 201, 202, as shown on structure 18. As shown, a diffusion barrier or etch stop is not used or needed between interconnects 520, 521 and laminate sheet 525, because laminate sheet 525 prevents electro-migration. The elimination of a diffusion barrier has the desirable effect of lowing the dielectric constant between interconnects.

Interconnects 620, 621 are formed in laminate sheet 525 through the use of a diffusion barrier 610, as shown on structure 19.

Finally, laminate sheet 525 and diffusion barrier 610 is removed on structure 20. As shown, structure 20 now includes two layers of interconnect devices 520, 521, 620, 621, and a dielectric between interconnects that is formed of air. Therefore, parasitic capacitance between the interconnect devices is reduced compared to prior art devices having ILD layers.

Additional metalization layers can be formed on structure 20 in a similar manner as previously described.

In another embodiment, only the trench level portion of laminate sheet 525 (i.e., the portion above dotted line 570 of structure 19) is removed, while the via level portion (i.e., the portion below dotted line 570) is not removed. The portion of laminate sheet 525 that remains provides thermomechanical stability to the vias of interconnects 620, 621. The removal of the trench level portion provides a low dielectric constant at the trench level.

In another embodiment, a thin metal layer, or metal shunt, is deposited on interconnects 620, 621. The metal shunt can also be added on top of all interconnects of a layered device. The metal shunt improves the electromigration performance of the device and can function as an etch stop layer. In one embodiment, the metal shunt is formed of cobalt and is deposited using an electroless plating method.

As described, a multi-layer damascene interconnect can be manufactured using a removable laminated sheet. The use of a laminated sheet provides a simplified manufacturing procedure and an improved dielectric between interconnects.

Several embodiments of the present invention are specifically illustrated and/or described herein. However, it will be appreciated that modifications and variations of the present invention are covered by the above teachings and within the purview of the appended claims without departing from the spirit and intended scope of the invention.

What is claimed is:

1. A method of fabricating a device, comprising:
laminating a first dielectric sheet on a substrate;
forming a first via opening in the first dielectric sheet; and
depositing a first conductive material into the first via opening.

2. The method of claim 1, further comprising:
removing the first dielectric sheet.

3. The method of claim 1, further comprising:
polishing the first conductive material to form a first interconnect layer.

4. The method of claim 1, wherein the first conductive material comprises copper.

5. The method of claim 1, wherein the deposition of the first conductive material includes the deposition of a copper seed layer, followed by an electroplating of copper.

6. The method of claim 1, further comprising depositing a first etch stop on the substrate.

7. The method of claim 1, wherein the first dielectric sheet is a single interlayer dielectric lamella.

8. The method of claim 1, wherein the first dielectric sheet is a multilayer lamella.

9. The method of claim 1, wherein the first dielectric sheet is a composite material.

10. The method of claim 1, further comprising:
removing a portion of the first dielectric sheet adjacent to a trench region of the first via opening.

11. The method of claim 1, further comprising:
depositing a metal shunt on the first conductive material.

12. The method of claim 3, further comprising:
laminating a second dielectric sheet on the first interconnect layer;
forming a second via opening in the second dielectric sheet; and
depositing a second conductive material into the second via opening.

13. A method of fabricating a device comprising:
forming a first interconnect layer on a substrate;
depositing a etch stop on the first interconnect layer;
laminating a dielectric sheet on the first etch stop;
forming a via opening in the dielectric sheet and the etch stop; and
depositing a conductive material into the via opening.

14. The method of claim 13, further comprising:
removing the dielectric sheet.

15. The method of claim 13, further comprising:
polishing the conductive material to form a second interconnect layer.

16. The method of claim 13, wherein the conductive material comprises copper.

17. The method of claim 13, wherein the deposition of the conductive material includes the deposition of a copper seed layer, followed by an electroplating of copper.

18. The method of claim 13, wherein the dielectric sheet is a single interlayer dielectric lamella.

19. The method of claim 13, wherein the dielectric sheet is a multilayer lamella.

20. The method of claim 13, wherein the dielectric sheet is a composite material.

21. A semiconductor device comprising:
a substrate;
a dielectric sheet coupled to said substrate;
a via opening formed in said dielectric sheet; and
a conductive material deposited in said via opening.

22. The semiconductor device of claim 21, further comprising an etch stop deposited on said substrate.

23. The semiconductor device of claim 21, wherein said conductive material comprises copper.

24. The semiconductor device of claim 21, wherein the dielectric sheet is a single interlayer dielectric lamella.

25. The semiconductor device of claim 21, wherein the dielectric sheet is a multilayer lamella.

26. The semiconductor device of claim 21, wherein the dielectric sheet is a composite material.

27. The semiconductor device claim 21, further comprising a metal stunt deposited on said conductive material.
